(19) United States
(12) Patent Application Publication
(10) Pub. No.: US 2001/0052752 A1
(43) Pub. Date: Dec. 20, 2001

(54) Thin film encapsulation of organic light emitting diode devices

(76) Inventors: Amalkumar P. Ghosh, Poughkeepsie, NY (US); Gary W. Jones, Lagrangeville, NY (US); Webster E. Howard, Lagrangeville, NY (US)

Correspondence Address: PATENT DEPARTMENT, SKADDEN, ARPS, SLATE, MEAGHER & FLOM LLP, FOUR TIMES SQUARE, NEW YORK, NY, 10036, US

(21) Appl. No.: 09/784,378

(22) Filed: Feb. 15, 2001

Related U.S. Application Data
(60) Provisional application No. 60/199,386, filed on Apr. 25, 2000.

(51) Int. Cl. H01J 1/62; H01J 63/04; B32B 15/08

(52) U.S. Cl. 313/512; 313/506; 428/461

(57) ABSTRACT

The present invention is directed to an OLED display device including an encapsulation assembly and methods for making such devices. The encapsulation assembly includes at least two layers, one of which is a dielectric oxide layer directly in contact with at least part of a substrate, and the other of which is preferably a polymer layer.

### CROSS-REFERENCE TO RELATED APPLICATIONS

This application claims priority to U.S. Provisional Patent Application No. 60/199386, filed Apr. 25, 2000.

### STATEMENT REGARDING FEDERALLY SPONSORED RESEARCH AND DEVELOPMENT

Not applicable.

### BACKGROUND OF THE INVENTION

The present invention relates to organic light emitting diode (“OLED”) devices.

Typical OLED devices use small molecule and polymer organic layers having many desirable properties but that are, at the same time, oxygen- and moisture-sensitive. If oxygen or water molecules reach these layers, the operational lifetime of the OLED device can be shortened significantly. It is thus desirable to provide a barrier as part of the device structure to prevent ambient moisture and oxygen from the reaching the sensitive layers.

OLED devices have been known for approximately two decades. All OLEDs work on the same general principles. An OLED device is typically made up of a stack of thin layers formed on a substrate. In the stack, a light-emitting layer of a luminescent organic solid, as well as adjacent semiconductor layers, are sandwiched between a cathode and an anode. The light-emitting layer may be selected from any of a multitude of fluorescent organic solids. Any of the layers, and particularly the light-emitting layer, may consist of multiple sublayers. Such devices are well known and understood by those skilled in the OLED art.

In a typical OLED, either the cathode or the anode is transparent. The cathode is typically constructed of a low work function material. The holes are typically injected from a high work function anode material into the organic material via a hole transport layer. The films may be formed by evaporation, spin casting or other appropriate polymer film-forming techniques, or chemical self-assembly. Thicknesses typically range from a few monolayers to about 1 to 2,000 angstroms.

### BRIEF SUMMARY OF THE INVENTION

The present invention is directed to an encapsulation assembly for an organic light emitting diode display device having a substrate, and at least one organic light emitting diode device formed thereon. The encapsulation layer is formed over the substrate and the at least one organic light emitting diode device. The encapsulation layer includes a first encapsulation layer formed directly on the substrate and the organic light emitting diode device, and a second encapsulation layer formed on the first encapsulation layer.

In accordance with one embodiment of the present invention, the first encapsulation layer is an oxide layer and the second encapsulation layer is a polymer layer. The polymer layer may include parylene.

In accordance with another embodiment of the present invention, the first encapsulation layer is a polymer layer and the second encapsulation layer is an oxide layer. At least a portion of the second encapsulation layer contacts the substrate. The second encapsulation layer preferably contacts the substrate around a perimeter of the substrate.

The present invention is also directed to a method of encapsulating an organic light emitting diode display device. The method in accordance with the present invention includes the steps of forming a first encapsulation layer directly on the substrate and the at least one organic light emitting diode device, and forming a second encapsulation layer on at least the first encapsulation layer.

In accordance with one embodiment of the present invention, the step of forming the first encapsulation layer includes the step of depositing an oxide layer directly on the substrate and the at least one organic light emitting diode device. It is contemplated that the step of depositing the oxide layer may include one of atomic layer epitaxy (ALE) or atomic layer deposition (ALD) processing to deposit the oxide layer (ALD is also known as atomic layer CVD or ALCVD). The step of forming the second encapsulation layer includes the step of depositing a polymer layer on the first encapsulation layer. This step may be performed at room temperature.

In accordance with another embodiment of the present invention, the step of forming the first encapsulation layer includes the step of depositing a polymer layer directly on a portion of the substrate and the at least one organic light emitting diode device. The step of forming the second encapsulation layer includes the step of depositing an oxide layer over the first encapsulation layer and a portion of the substrate. At least a portion of the second encapsulation layer contacts the substrate.

Thus, the present invention is directed to an organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising a dielectric oxide, wherein the dielectric oxide of the encapsulation oxide layer lies over and in direct contact with both the substrate and the at least one organic light emitting diode device; and a second encapsulation layer, wherein the second encapsulation layer covers the first encapsulation layer.

The present invention is also directed to an organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising a dielectric oxide deposited using a process selected from the group consisting of ALE and ALD (ALD is also known as ALCVD), wherein the dielectric oxide of the first encapsulation oxide layer lies over and is in direct contact with both the substrate and the at least one organic light emitting diode device; and a second encapsulation layer comprising a polymer, wherein the second encapsulation layer covers the first encapsulation layer. The second encapsulation polymer layer of this device preferably comprises a parylene, and in particular, parylene N, parylene C, or parylene D, and more preferably comprises parylene C. Furthermore, the dielectric oxide of the oxide layer preferably comprises Al₂O₃, SiO₂, TiO₂, ZrO₂, MgO, HfO₂, Ta₂O₅, aluminum titanium oxide, and tantalum hafnium oxide, more preferably comprises Al₂O₃ or SiO₂, and most preferably comprises Al₂O₃.

The present invention is also directed to an organic light emitting diode display device comprising a substrate, at least one organic light emitting diode device formed thereon, and an encapsulation assembly formed over the substrate and the at least one organic light emitting diode device, the encapsulation assembly comprising: a patterned first encapsulation layer wherein the pattern of the first encapsulation layer leaves a perimeter of the substrate exposed around the at least one organic light emitting diode device; and a second encapsulation layer comprising an ALE dielectric oxide or an ALD dielectric oxide, wherein the second encapsulation layer covers both the exposed perimeter of the substrate and the first encapsulation layer. Preferably, the first encapsulation layer comprises a polymer, and more preferably, that polymer comprises a parylene, and in particular, parylene N, parylene C, or parylene D. Most preferably, that polymer comprises parylene C.

The present invention is also directed to an upwardly emitting organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising Al₂O₃ deposited using a process selected from the group consisting of ALE and ALD, wherein the Al₂O₃ of the first encapsulation oxide layer lies over and is in direct contact with both the substrate and the at least one organic light emitting diode device; and a second encapsulation polymer layer, wherein the second encapsulation layer comprises parylene C and covers the first encapsulation layer. Optionally, this device may further comprise a layer of SiO₂, wherein the layer of SiO₂, covers the second encapsulation polymer layer. Preferably, the first encapsulation oxide layer is substantially pure, and consists essentially of Al₂O₃. Also preferably, the second encapsulation layer consists essentially of parylene C.

The present invention is also directed to a method of encapsulating an organic light emitting diode display device, wherein the organic light emitting diode display device comprises a substrate, and at least one organic light emitting diode device formed thereon, the method comprising the steps of: depositing a first encapsulation dielectric oxide layer using a method selected from the group consisting of ALE and ALD, wherein the encapsulation dielectric oxide layer lies over and in direct contact with both the substrate and the at least one organic light emitting diode device; and depositing a second encapsulation layer, wherein the second encapsulation layer covers the first encapsulation layer.

A second method of encapsulating an organic light emitting diode display device is also part of the present invention, wherein the organic light emitting diode display device comprises a substrate, and at least one organic light emitting diode device formed thereon, the method comprising the steps of: depositing a first encapsulation dielectric oxide layer using a method selected from the group consisting of ALE and ALD, wherein the first encapsulation oxide layer lies over and is in direct contact with both the substrate and the at least one organic light emitting diode device; and depositing a second encapsulation polymer layer, wherein the second encapsulation layer covers the first encapsulation layer. Preferably, the step of depositing the oxide layer uses ALD. In this method, the step of depositing the second encapsulation polymer layer may be performed with each of the substrate, the at least one organic light emitting device thereon and the first dielectric oxide encapsulation layer at room temperature. Preferably in this method, the step of depositing the second encapsulation polymer layer further comprises a step of forming vapor phase monomer species able to condense and polymerize on the first dielectric oxide encapsulation layer at a temperature less than about 40° C., and most preferably, at about room temperature.

It is to be understood that both the foregoing general description and the following detailed description are exemplary and explanatory only, and are not restrictive of the invention as claimed. The accompanying drawings, which are incorporated herein by reference and which constitute apart of this specification, illustrate certain embodiments of the invention, and together with the detailed description serve to explain the principles of the present invention.

### BRIEF DESCRIPTION OF THE SEVERAL VIEWS OF THE DRAWING

FIG. 1 is a cross sectional view of a plurality of OLED devices on a single substrate having an encapsulation assembly in accordance with an embodiment of the present invention;

FIG. 2 is a cross sectional view of an OLED device resulting from dicing of the plurality of devices depicted in FIG. 1;

FIG. 3 is a cross sectional view of a plurality of OLED devices on a single substrate having an encapsulation assembly in accordance with another embodiment of the present invention;

FIG. 4 is a cross sectional view of an OLED device resulting from dicing of the plurality of devices depicted in FIG. 3; and

FIG. 5 is a top view of a plurality of partially constructed OLED devices on a single substrate having a partial encapsulation assembly according to an embodiment of the present invention, and showing the locations where the substrate of the finished device are to be cut during the dicing operation.

### DETAILED DESCRIPTION OF THE INVENTION

The present invention is directed to OLED devices having a multilayer encapsulation assembly. While not limited to such devices, the encapsulation assembly used in the present invention is particularly well-suited for the fabrication of full-color displays, and particularly full-color miniature OLED displays. Fabrication of color OLED displays generally requires side-by-side patterning of red, green and blue sub-pixels. Since these devices are extremely moisture sensitive, any kind of wet processing directly on the OLED stack is normally not possible. Use of shadow masks during evaporation of organic materials to pattern the colors is not feasible for high resolution displays. As such, most color OLED devices are fabricated using either color filters or color changing media (CCM) that are typically patterned on a separate substrate. In order to be able to fabricate color filters on OLED substrates, which involves various wet chemical processing, it is necessary to hermetically encapsulate the OLED device layers.

In the case of full color OLED display fabrication using color filters or CCM on a separate face plate, it is important that the face plate be aligned to the device plate with very high precision. In the case of high resolution miniature displays, for example, the alignment accuracy can be as high as ˜0.5 μm. In addition, the gap between the two substrates needs to be minimized in order to avoid color cross-talk between the sub-pixels (especially because the OLED device emission is Lambertian). Furthermore, the two substrates need to be perfectly parallel to each other so that no undesirable effects such as Newton's rings, etc. affect the display performance.

The encapsulation assemblies of the OLED devices of the present invention always have an oxide layer in direct contact with the substrate. This contact forms a perimeter around the OLED stacks and a barrier against moisture incursion. preferably, the oxide layer or layers of the present invention are formed using atomic layer epitaxy (ALE) or by atomic layer deposition (ALD). ALD is also sometimes referred to a atomic layer chemical vapor deposition or ALCVD, and the two terms are used interchangeably herein. ALE, and ALD oxide layers are conformal and avoid the propagation of defects due to uneven substrate surfaces, and thus form adequate barriers against moisture incursion.

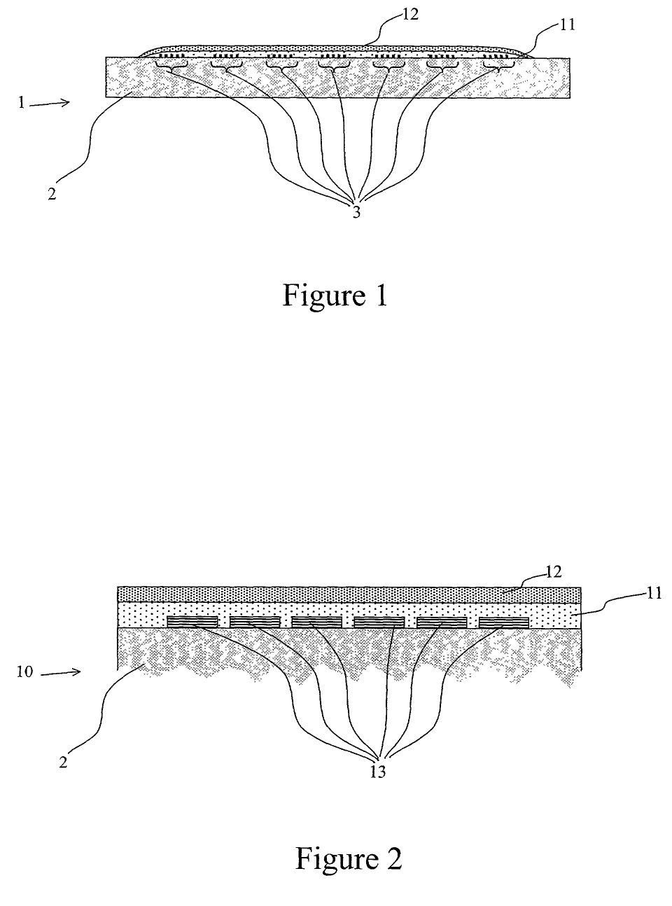

A first embodiment of the present invention is illustrated in FIGS. 1 and 2. FIG. 1 illustrates an encapsulation assembly 1 for a plurality of OLED display devices 3 on a substrate 2. The OLED display devices include at least one OLED stack formed on the substrate. The OLED stack or stacks have a conventional construction including a pair of conducting layers (anode and cathode) and an organic stack sandwiched there between. The top conductor layer of the stacks may be a low pinhole density transparent conductor top layer (for example ITO), which forms a first barrier. For an up-emitting OLED device, this top conductor layer acts as a cathode, while for down-emitting devices, this top conductor layer acts as an anode.

The encapsulation assembly of the OLED device of this first embodiment includes a first encapsulation layer 11 and a second encapsulation layer 12. The first encapsulation layer 11 is formed of a dielectric oxide layer and is deposited by ALE or ALD. The second encapsulation layer 12 preferably includes a polymer. In this first embodiment, the oxide layer is formed as the first encapsulation layer so that there is no possibility of moisture permeating from the edges of the display. Optionally on top of encapsulation layer 12, is laid down additional encapsulation layers and color filter means or color changing means (CCM; not shown in the figure). Such color filter means or CCM may be patterned directly on encapsulation layer 12, or preferably on a thin layer of SiO₂ or other dielectric oxide layered on top of layer 12. The color filter or CCM fabrication may use any of a variety of well known wet processing techniques where the layer 12 material is sufficiently resistant to the processing conditions. Optionally, on top of the color filtering or changing means, additional encapsulation layers may be laid down to protect the color filtration or changing elements.

Following production of the plurality of OLED display devices illustrated in FIG. 1, the individual OLED display devices 10 are obtained by dicing the assembly of FIG. 1. This dicing operation generates individual devices as illustrated in FIG. 2, with individual OLED stacks 13 on top of a substrate 2, with encapsulation layer 11 forming a seal with the substrate, and with encapsulation layer 12 protecting layer 11 from mechanical and chemical damage.

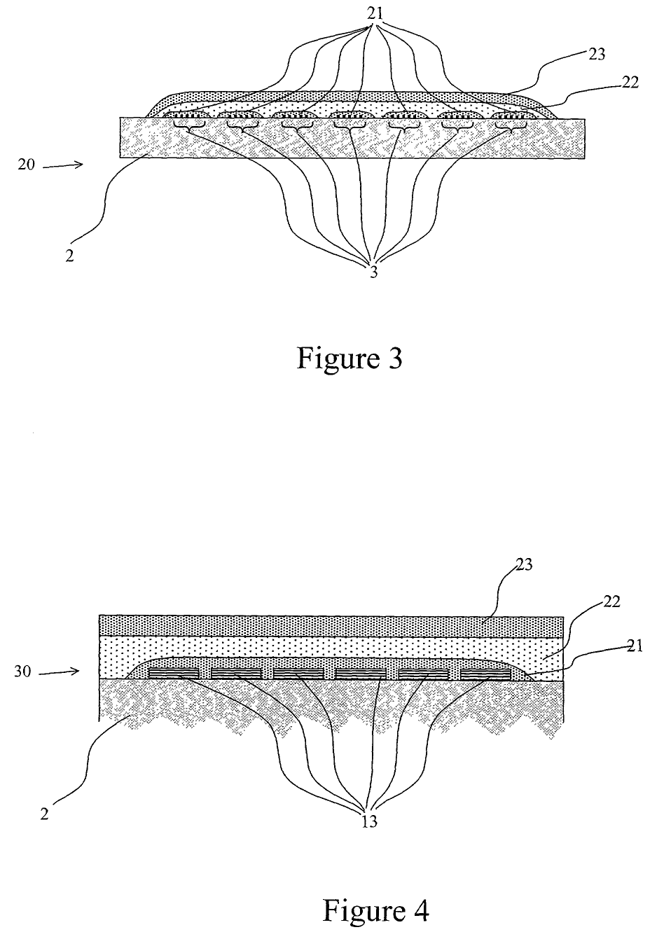

A second embodiment of the present invention is illustrated in FIGS. 3, 4 and 5. FIG. 3 illustrates an encapsulation assembly 20 for a plurality of OLED display devices 3 on a substrate 2. The OLED display devices include at least one OLED stack formed on the substrate. The OLED stack or stacks have a conventional construction including a pair of conducting layers (anode and cathode) and an organic stack sandwiched there between. The top conductor layer of the stacks 3 may be a low pinhole density transparent conductor top layer (for example ITO), which forms a first barrier. For an up-emitting OLED device, this top conductor layer acts as a cathode, while for down-emitting devices, this top conductor layer acts as an anode.

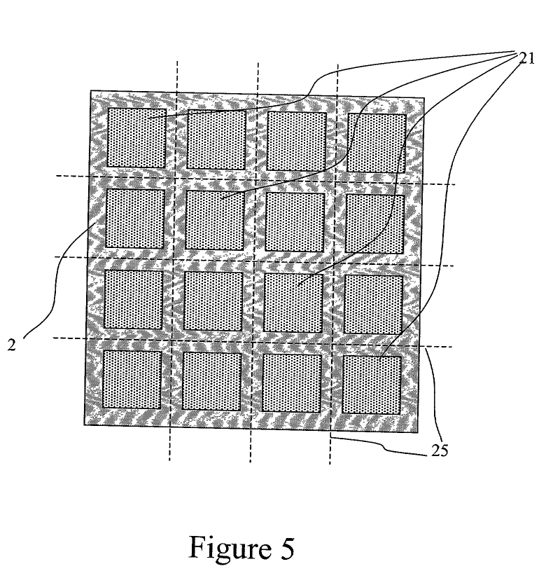

The encapsulation assembly of this second embodiment includes a first encapsulation layer 21 and a second encapsulation layer 22. The first encapsulation layer 21 is formed of a polymer layer and is patterned to leave exposed a portion of the substrate surface in between the individual OLED devices. Such patterning may be achieved by any well-known, conventional means, including shadow masking before layer formation and ablation (e.g. laser ablation) following layer formation. FIG. 5 is a top view of the substrate 2 with the first encapsulation layer 21 of this embodiment shown without a second encapsulation layer laid down over it. The dashed lines 25 in FIG. 5 indicate where the substrate would be cut as part of the dicing operation following completion of the encapsulation assembly. The second encapsulation layer 22 in FIG. 3 is formed of one or more oxide layers and is deposited by ALE or ALD. In this second embodiment, the oxide layer 22 is formed over both the encapsulation layer 21 and the exposed portions of the substrate 2. The areas of oxide layer 22 that are laid down over the exposed portions of the substrate 2 form a seal and barrier to water so that there is much less possibility of moisture permeating from the edges of the display. Optionally on top of encapsulation layer 22, is laid down a third encapsulation layer 23, preferably formed of one or more polymer layers to provide chemical and mechanical protection to the device. Optionally, on top of this third encapsulation layer 23 is laid down color filter means or CCM (not shown in the figure); this color filter means or CCM is more preferably laid down on top of an SiO₂ or other oxide layer (not shown) laid on top of layer 23. Such color filter means or CCM may be patterned directly on encapsulation layer 23 or on the additional SiO₂ or other oxide layer using any well known wet processing technique where the layer 23 or the additional SiO₂ or other oxide layer material is sufficiently resistant to the processing conditions. Optionally, on top of the color filtering or changing means, additional encapsulation layers may be laid down to protect the color filtration or changing elements.

Following production of the plurality of OLED display devices illustrated in FIG. 3, the individual OLED display devices 30 of FIG. 4 are obtained by dicing assembly 20 of FIG. 3. The individual devices illustrated in FIG. 4 have individual OLED stacks 13 on top of a substrate 2, with encapsulation layer 22 forming a seal with the substrate, and with optional encapsulation layer 23 protecting layer 21 from mechanical and chemical damage.

For a high resolution display device, the actual number of stacks 13 in either embodiment will be much greater than that illustrated in the figures, and for a full color display, can reach 4 to 5 million stacks per display. Furthermore, the figures illustrating particular embodiments show rectangular devices, with orthogonal patterning in some cases; the present invention works equally well with other OLED shapes and layout patterns (for example, circular and elliptical) and methods for fabricating such devices are well known.

The use of an oxide layer that is highly conforming and that can be deposited at a temperature low enough for the OLED layers to survive is ideal. The oxide layer preferably is formed from Al₂O₃ or SiO₂, and most preferably from Al₂O₃. The thickness of the layer should be high enough to provide a moisture barrier, but low enough to ensure high light transmission. Al₂O₃, layers are typically around 500 Å thick, but can range from 200 to 750 Å, and preferably from 400 to 600 Å. The present invention, however, is not limited to Al₂O₃ and SiO₂; rather, other dielectric oxides (for example TiO₂, ZrO₂, MgO, HfO₂, Ta₂O₅, and multilayer oxides such as aluminum titanium oxide and tantalum hafnium oxide, etc.) having similar properties and conformity may be used as the oxide layer.

The oxide layer is preferably deposited using Atomic Layer Epitaxy (ALE) or Atomic Layer Deposition (ALD) processing, which provide a highly conformal oxide layer that can be deposited without any energetic particles impinging the OLED surface. A low temperature ALD deposition process (approximately 100-120° C.) provides a good conformal coating of an oxide such as Al₂O₃ and SiO₂. This oxide layer then forms the primary moisture barrier layer. However, such oxides are sometimes attacked by highly basic chemicals, which may be used during the color filter processing.

In order to protect the oxide layer from any kind of chemical attack, a layer deposited at or below room temperature of highly chemically resistant polymer material may be used. Preferred polymers for this layer are the parylenes. The chemical inertness and the ease of deposition of parylenes are well known. Furthermore, parylenes form highly conformal coatings that help in covering any stray particles and pinholes. Parylene coating is a room temperature deposition process that does not require any ultraviolet curing. The three standard parylenes are parylene N, parylene C and parylene D:

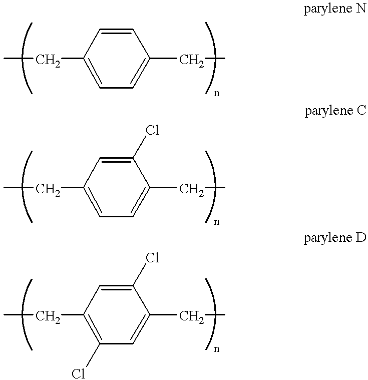

While any parylene is suitable for the polymer layer of the devices of the present invention, parylene C is preferred because it is lowest of the three in oxygen permeability and moisture vapor transmission. Parylenes are deposited using standard techniques, starting from a dimeric form diparaxylylene (abbreviated DPX, DPX-C and DPX-D for parylene N, parylene C and parylene D, respectively). The dimer is evaporated and sent through a pyrolysis zone where the dimer dibenzylic bonds homolyze to form highly-reactive monomer species as illustrated below for parylene C:

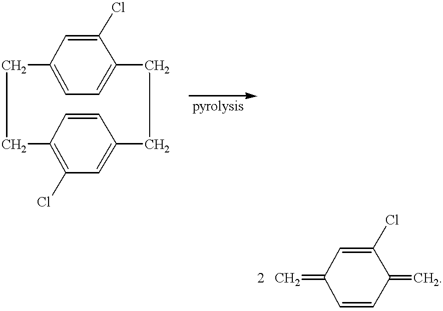

The monomers then travel to the deposition site, where they condense and polymerize on the device on contact. Optionally, and preferably for purposes of the present invention, a well-known adhesion promoter such as trichlorosilane or γ-methacryloxypropylenetrimethoxysilane may be vapor deposited on the device prior to deposition of the parylene.

The present invention, however, is not limited to parylenes for the polymer layers. Any conformal, chemically resistant polymer with suitable barrier properties may be used, as long as it polymerizes on contact, near, at or below room temperature. In particular, suitable polymers are those that may be formed from vapor phase monomer species that will condense and polymerize on a surface at a temperature below about 40° C., and preferably at room temperature (approximately 25° C.). For example, polymers laid down using plasma-enhanced polymer deposition techniques as disclosed in U.S. patent application Ser. Nos. 09/212,780 and 09/212,774, both filed on Dec. 16, 1998, and in International Patent Application Publications WO 35605 and WO 35604, both published Jun. 22, 2000, are also suitable for the polymer layer of the present invention.

The encapsulation assembly of present invention will now be illustrated by way of a non-limiting example.

An active matrix silicon wafer layered with a plurality of OLED devices and maintained under an essentially oxygen and moisture free (less the 1 ppm) nitrogen atmosphere is placed in the load chamber of an ASM Microchemistry Pulsar 2000 ALCVD apparatus with attached IN-USA ozone generator. The load chamber is then evacuated to a pressure of 0.1 millitorr. The wafer is then moved from the load chamber into the reactor chamber of the ALCVD device. The reactor chamber is then evacuated to a pressure of 0.001 millitorr and then continuously purged with nitrogen at 400 sccm. The wafer and reactor chamber are then heated to 100° C. and maintained at that temperature during the entire deposition process. Ozone is then introduced into the reactor chamber at 132 grams per normalized cubic meter (GNM3; oxygen flow rate on the IN-USA generator set to 150 sccm) with an ozone pulse duration of 0.5 sec, followed by a purge (nitrogen alone) for 0.5 sec. Trimethyl aluminum (TMA) gas is then introduced into the chamber for 0.1 sec with a nitrogen flow in the TMA source line of 400 sccm and a TMA source line pressure of 240 Torr. The TMA reacts and deposits an atomic layer of Al₂O₃ on the active matrix silicon wafer layered with a plurality of OLED devices. The reactor chamber is then purged again with nitrogen for 0.2 sec. The series of steps beginning with the ozone pulse is then repeated 800 times to lay down subsequent atomic layers of Al₂O₃ to build up an overall layer thickness of approximately 500 Å (approximate growth rate of 0.54-0.59 Å/cycle).

The active matrix silicon wafer layered with a plurality of OLED devices and layered with Al₂O₃ is removed from the ALCVD apparatus and transferred into the deposition chamber of a Specialty Coating Systems Model 2060V deposition apparatus with in situ adhesion promoter capability. The pyrolysis furnace intermediate between the first and deposition chambers is heated to and maintained at a temperature of 680° C. A 2.5 g sample of DPX-C in an aluminum boat is introduced into the first chamber of the apparatus, and 1 mL sample of A-174 (available from Specialty Coating Systems) is loaded into the in situ adhesion promoter furnace. The entire system is then evacuated to a pressure of 1 millitorr and the adhesion promoter furnace is heated to 190° C. and held at that temperature until the deposition chamber pressure returns to 1 millitorr. The first chamber temperature is then raised to 150° C. The DPX-C dimer evaporates and passes into the pyrolysis furnace where it is pyrolysed to monomer, which passes into the deposition chamber. The monomer deposits and polymerizes as parylene C on the active matrix silicon wafer layered with a plurality of OLED devices layered with Al₂O₃.

The active matrix silicon wafer layered with a plurality of OLED devices layered with Al₂O₃ and parylene C layers is then transferred into an Ulvac Model MMI electron beam evaporator into the source crucible of which has been loaded SiO₂. The SiO₂ is pre-melted and then evaporated at a beam energy of 6.1 kV at 0.29 amperes at a pressure of 0.001 millitorr. The finished assembly is then placed in an oven under ambient pressure nitrogen gas for 30 minutes. This SiO₂ layer provides a hard surface for color filter or CCM fabrication and avoids scumming by the parylene layer.

It will be apparent to those skilled in the art that various modifications and variations may be made in the preparation and configuration of the present invention without departing from the scope and spirit of the present invention. For example, additional protection may be provided by patterning an organic top layer (e.g. laser ablate parylene or photo process O₂ plasma), ALE or sputter inorganic (e.g. 500 Å of Al₂O₃), and a second layer of parylene. After processing and gluing with cover glass (e.g. epoxy) O₂ plasma can be used to remove polymer, chemical etch (e.g. phosphoric acid) can be used to remove Al₂O₃ using cover glass and adhesive as a mask. Thus, it is intended that the present invention covers the modifications and variations of the invention, provided they come within the scope of the appended claims and their equivalents.

Various references have been cited above, all of which are incorporated by reference in their entireties as though fully set forth.

1. An organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising a dielectric oxide, wherein the dielectric oxide of the encapsulation oxide layer lies over and in direct contact with both the substrate and the at least one organic light emitting diode device; and a second encapsulation layer, wherein the second encapsulation layer covers the first encapsulation layer.

2. An organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising a dielectric oxide deposited using a process selected from the group consisting of ALE and ALD, wherein the dielectric oxide of the first encapsulation oxide layer lies over and is in direct contact with both the substrate and the at least one organic light emitting diode device; and a second encapsulation layer comprising a polymer, wherein the second encapsulation layer covers the first encapsulation layer.

3. The organic light emitting diode display device according to claim 2, wherein the polymer of the second encapsulation layer comprises a parylene.

4. The organic light emitting diode display device according to claim 3, wherein the parylene is selected from the group consisting of parylene N, parylene C, and parylene D.

5. The organic light emitting diode display device according to claim 2, wherein the second encapsulation polymer layer comprises parylene C.

6. The organic light emitting diode display device according to claim 2, wherein the first encapsulation oxide layer comprises a dielectric oxide selected from the group consisting of Al₂O₃, SiO₂, TiO₂, ZrO₂, MgO, HfO₂, Ta₂O₅, aluminum titanium oxide, and tantalum hafnium oxide.

7. The organic light emitting diode display device according to claim 3, wherein the first encapsulation oxide layer comprises a dielectric oxide selected from the group consisting of Al₂O₃, SiO₂, TiO₂, ZrO₂, MgO, HfO₂, Ta₂O₅, aluminum titanium oxide, and tantalum hafnium oxide.

8. The organic light emitting diode display device according to claim 4, wherein the first encapsulation oxide layer comprises a dielectric oxide selected from the group consisting of Al₂O₃, SiO₂, TiO₂, ZrO₂, MgO, HfO₂, Ta₂O₅, aluminum titanium oxide, and tantalum hafnium oxide.

9. The organic light emitting diode display device according to claim 2, wherein the first encapsulation oxide layer comprises a dielectric oxide selected from the group consisting of Al₂O₃ and SiO₂.

10. The organic light emitting diode display device according to claim 3, wherein the first encapsulation oxide layer comprises a dielectric oxide selected from the group consisting of Al₂O₃ and SiO₂.

11. The organic light emitting diode display device according to claim 4, wherein the first encapsulation oxide layer comprises a dielectric oxide selected from the group consisting of Al₂O₃ and SiO₂.

12. The organic light emitting diode display device according to claim 2, wherein the dielectric oxide of the first encapsulation oxide layer comprises Al₂O₃.

13. The organic light emitting diode display device according to claim 3, wherein the dielectric oxide of the first encapsulation oxide layer comprises Al₂O₃.

14. The organic light emitting diode display device according to claim 4, wherein the dielectric oxide of the first encapsulation oxide layer comprises Al₂O₃.

15. An organic light emitting diode display device comprising a substrate, at least one organic light emitting diode device formed thereon, and an encapsulation assembly formed over the substrate and the at least one organic light emitting diode device, the encapsulation assembly comprising: a patterned first encapsulation layer wherein the pattern of the first encapsulation layer leaves a perimeter of the substrate exposed around the at least one organic light emitting diode device; a second encapsulation layer comprising an oxide selected from the group consisting of an ALE dielectric oxide and an ALD dielectric oxide, wherein the second encapsulation layer covers both the exposed perimeter of the substrate and the first encapsulation layer.

16. The organic light emitting diode display device according to claim 15, wherein the first encapsulation layer comprises a polymer.

17. The organic light emitting diode display device according to claim 16, wherein the polymer comprises a parylene.

18. The organic light emitting diode display device according to claim 17, wherein the polymer comprises a polymer selected from the group consisting of parylene N, parylene C, and parylene D.

19. The organic light emitting diode display device according to claim 18, wherein the polymer comprises parylene C.

20. An upwardly emitting organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer comprising Al₂O₃ deposited using a process selected from the group consisting of ALD and ALE, wherein the first encapsulation oxide layer lies over and is in direct contact with both the substrate and the at least one organic light emitting diode device; and a second encapsulation polymer layer, wherein the second encapsulation layer comprises parylene C and covers the first encapsulation layer.

21. The organic light emitting diode display device according to claim 20 further comprising a layer of SiO₂, wherein the layer of SiO₂, lies over and covers the second encapsulation polymer layer.

22. An upwardly emitting organic light emitting diode display device comprising a substrate, at least one organic light emitting diode device formed thereon, and an encapsulation assembly formed over the substrate and the at least one organic light emitting diode device, the encapsulation assembly comprising: a first encapsulation oxide layer consisting essentially of Al₂O₃ deposited using a process selected from the group consisting of ALE and ALD, wherein the Al₂O₃ of the first encapsulation oxide layer lies over and is in direct contact with both the substrate and the at least one organic light emitting diode device; and a second encapsulation polymer layer, wherein the second encapsulation layer consists essentially of parylene C and lies over and covers the first encapsulation layer.

23. The organic light emitting diode display device according to claim 22 wherein the Al₂O₃ is deposited using ALD.

24. The organic light emitting diode display device according to claim 23 further comprising a third encapsulation layer consisting essentially of SiO₂, wherein the third encapsulation layer lies over and covers the second encapsulation polymer layer.

25. A method of encapsulating an organic light emitting diode display device, wherein the organic light emitting diode display device comprises a substrate, and at least one organic light emitting diode device formed thereon, the method comprising the steps of:
depositing a first encapsulation dielectric oxide layer using a method selected from the group consisting of ALE and ALD, wherein the encapsulation dielectric oxide layer lies over and in direct contact with both the substrate and the at least one organic light emitting diode device; and
depositing a second encapsulation layer, wherein the second encapsulation layer covers the first encapsulation layer.

26. A method of encapsulating an organic light emitting diode display device, wherein the organic light emitting diode display device comprises a substrate, and at least one organic light emitting diode device formed thereon, the method comprising the steps of:
depositing a first encapsulation dielectric oxide layer using a method selected from the group consisting of ALE and ALD, wherein the first encapsulation oxide layer lies over and is in direct contact with both the substrate and the at least one organic light emitting diode device; and
depositing a second encapsulation polymer layer, wherein the second encapsulation layer covers the first encapsulation layer.

27. The method according to claim 2, wherein the step of depositing the oxide layer uses ALD.

28. The method according to claim 26, wherein the step of depositing the oxide layer uses ALD.

29. The method according to claim 26, wherein the step of depositing the second encapsulation polymer layer is performed with each of the substrate, the at least one organic light emitting device thereon and the first dielectric oxide encapsulation layer at room temperature.

30. The method according to claim 26, wherein the step of depositing the second encapsulation polymer layer further comprises a step of forming vapor phase monomer species able to condense and polymerize on the first dielectric oxide encapsulation layer at a temperature less than about 40° C.
